(19) United States
(12) Patent Application Publication
(10) Pub. No.: US 2025/0283918 A1
(43) Pub. Date: Sep. 11, 2025

(54) MEASUREMENT OF HIGH CURRENTS USING A SHUNT

(71) Applicant: SAGEMCOM ENERGY & TELECOM SAS, BOIS-COLOMBES (FR)

(72) Inventors: Christophe GRINCOURT, BOIS-COLOMBES (FR); Henri TEBOULLE, BOIS-COLOMBES (FR)

(21) Appl. No.: 19/065,679

(22) Filed: Feb. 27, 2025

(30) Foreign Application Priority Data
Mar. 5, 2024 (FR) FR2402201

(51) Int. Cl. G01R 15/14; G01R 22/06

(52) U.S. Cl. CPC G01R 15/146; G01R 22/061

(57) ABSTRACT

A current measurement device arranged to measure a main current passing therethrough and includes a first element which is electrically conductive and which includes a shunt and a second element which is electrically conductive. Each end of the first element is fastened to a separate end of the second element by an electrically conductive connection such that the main current is split into a first current flowing in the first element and a second current flowing in the second element, the shunt thus making it possible to measure the first current, which is representative of the main current.

The invention relates to current measurement devices.

### BACKGROUND

Shunts are conventionally used in electricity meters to measure the current supplied by a distribution network to an installation. The measurements of the current are then used to evaluate the power and electrical energy consumed by the installation.

FIG. 1 shows a prior-art shunt 1. This shunt 1 is intended to be integrated in an electricity meter that measures currents of less than 100 A.

The shunt 1 comprises a main segment 2 in the form of a rectangular plate, and a first terminal 3a and a second terminal 3b located at the ends of the main segment 2. Copper plates 4a, 4b are fastened to the ends of the shunt 1 on either side thereof. Wires (not shown) are connected to each of the terminals 3a, 3b and allow the voltage across the terminals of the shunt 1 to be measured. The current flowing in the shunt 1 is evaluated on the basis of these voltage measurements.

By way of example, the shunt 1 has a length l₁ of 5 mm, a height h₁ of 8 mm and a thickness e₁ of 1.79 mm, and therefore a cross section along a plane perpendicular to its length l₁ of 14.3 mm². The impedance of the shunt 1 at 20° C. (almost entirely resistive at the frequencies under consideration) is then 150μΩ.

The two copper plates 4a, 4b each have a length of 12.5 mm, a height of 8 mm, a thickness of 1.79 mm and an impedance at 20° C. of 15μΩ. The total impedance of the two copper plates at 20° C. is 30μΩ.

An electrically conductive part having a total length of 30 mm and a total impedance at 20° C. of 180μΩ is thus obtained.

This shunt 1 was designed for a maximum current to be of 90 A. The power dissipated inside the measured electricity meter by the shunt 1 at this current is 1.46 W, which is acceptable.

The aim is to design a current measurement device for a meter that measures high currents (200 A or 320 A, for example). At first glance, it would seem logical to use a shunt such as that in FIG. 1.

However, if a current of 200 A passes through this shunt 1, the power dissipated at this high current is 7.2 W. At a current of 320 A, the power obtained is 18.44 W.

These powers are too high for electricity meters which, in their standard design, cannot dissipate those powers effectively.

To reduce the dissipated power, the height and/or thickness of the shunt can be increased.

For example, at a shunt height of 100 mm, the dissipated power obtained is 1.47 W. With a constant height, a thickness of 23 mm would be required in order to obtain a comparable result. However, these dimensions are too large for the shunt to be integrated in a standard electricity meter. Furthermore, these solutions lead to significant additional costs.

It is also possible to reduce the length of the shunt. However, even at a length of 1 mm, which is the absolute minimum length, the dissipated power obtained is 6.44 W, which is again too high.

### Object

The object of the invention is to measure high currents using a measurement shunt while limiting the dissipated power, with very good measurement accuracy and lower costs.

### SUMMARY

With a view to achieving this object, a current measurement device is proposed, which is arranged for measuring a main current passing therethrough and comprises:
a first element which is electrically conductive and which includes a shunt;
a second element which is electrically conductive; each end of the first element being fastened to a separate end of the second element by an electrically conductive connection such that the main current is split into a first current flowing in the first element and a second current flowing in the second element, the shunt thus making it possible to measure the first current, which is representative of the main current.

The materials used to make the first element (and thus the shunt) and the second element can be selected such that the impedance of the first element is much higher than that of the second element. The power dissipated in the shunt when the first current passes therethrough and, more generally, the power dissipated by the current measurement device when the main current passes therethrough are then significantly lower than if the entire main current passed through the shunt.

The first current flowing in the shunt is a resemblance of the main current, and the accuracy of the measurement is very high. If necessary, the temperature drift differences in the materials used can be compensated for.

The cost of the current measurement device is low. This device uses a “classic” shunt which can be used for low currents, and a second element which can be a very simple and inexpensive part or segment of a part.

In addition, a current measurement device as described above is proposed, comprising a part that comprises a side in which there is formed a notch that defines a recessed portion extending along a segment of a length of the part, and a non-recessed portion extending along said segment of the length of the part, the second element being said non-recessed portion, and the first element extending in the notch so as to leave a non-electrically conductive space between the first element and the second element.

In addition, a current measurement device as described above is proposed, in which each end of the first element comprises a first cavity formed in its body, and each end of the second element comprises a second cavity formed in its body, the first element and the second element having their ends nested in such a way that a bottom of the first cavity in each end of the first element abuts a bottom of the second cavity in a separate end of the second element.

In addition, a current measurement device as described above is proposed, in which the second element is made of at least one material comprising a copper alloy.

In addition, a current measurement device as described above is proposed, in which the first element comprises the shunt and two plates, which are fastened to the shunt and positioned on either side of the shunt.

In addition, a current measurement device as described above is proposed, in which the shunt is made of at least one material comprising Manganin.

In addition, a current measurement device as described above is proposed, in which each electrically conductive connection is established by a spot-welding operation.

In addition, a current measurement device as described above is proposed, in which an electrical resistance of the first element is between 5 times and 100 times an electrical resistance of the second element.

In addition, an electrical apparatus including a current measurement device as described above is proposed, the electrical apparatus comprising a processing unit arranged to:
measure a voltage across the terminals of the shunt;
evaluate the main current on the basis of said voltage.

In addition, an electrical apparatus as described above is proposed, further comprising a temperature sensor, the processing unit being further arranged to acquire temperature measurements produced by the temperature sensor and to compensate, depending on said temperature measurements, for a temperature drift difference of an electrical resistance of the first element and an electrical resistance of the second element.

In addition, an electrical apparatus as described above is proposed, the electrical apparatus being an electricity meter.

In addition, an electrical apparatus as described above is proposed, the electrical apparatus being arranged to measure a main current greater than 100 A using the current measurement device.

In addition, a current measurement method is proposed, which is carried out in the processing unit of the electrical apparatus as described above and comprises the steps of:
measuring a voltage across the terminals of the shunt;
acquiring the temperature measurements produced by the temperature sensor;
determining, depending on the temperature, a value of a compensation parameter for compensating for the temperature drift difference of the electrical resistance of the first element and of the electrical resistance of the second element;
correcting the voltage across the terminals of the shunt using said value of said compensation parameter;
evaluating the main current on the basis of the corrected voltage.

In addition, a computer program is proposed, comprising instructions which cause the processing unit of the electrical apparatus as described above to execute the steps of the current measurement method as described above.

In addition, a computer-readable storage medium is proposed, on which the computer program as described above is stored.

The invention will be better understood in the light of the following description of a particular, non-limiting embodiment of the invention.

### BRIEF DESCRIPTION OF THE DRAWINGS

Reference will be made to the accompanying drawings, in which:

FIG. 1 is a perspective view of a prior-art shunt;

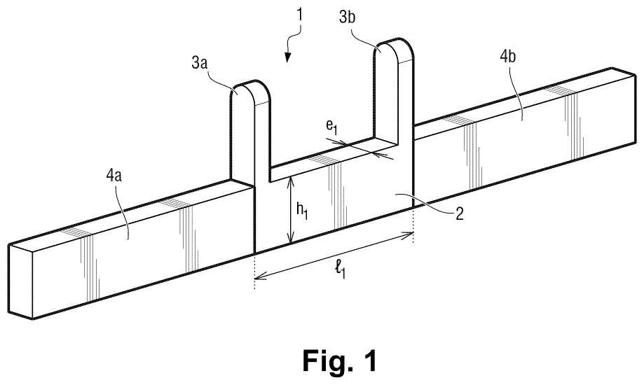

FIG. 2 shows a meter in which a current measurement device is integrated;

FIG. 3 is a perspective view of the current measurement device;

FIG. 4 is a side view of the current measurement device.

### DETAILED DESCRIPTION

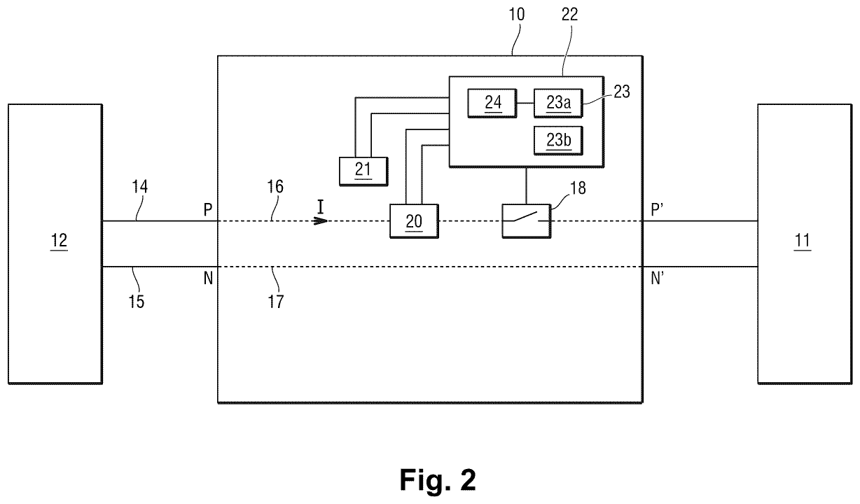

With reference to FIG. 2, the electricity meter 10 is intended for measuring the electrical energy consumption of an installation 11. This electrical energy is supplied to the installation 11 by a distribution network 12. The distribution network 12 comprises a phase line 14 and a neutral line 15. In this case, the meter 10 is a single-phase meter.

The meter 10 comprises an upstream phase terminal P connected to the phase line 14 of the network 12, and an upstream neutral terminal N connected to the neutral line 15 of the network 12. The meter 10 also comprises a downstream phase terminal P′ and a downstream neutral terminal N′.

In this case, the term “upstream” means on the distribution network 12 side, and the term “downstream” means on the installation 11 side.

The downstream phase terminal P′ and the downstream neutral terminal N′ of the meter 10 are connected to the installation 11, optionally via respective switches integrated in a circuit breaker located outside the meter 10 and not shown here.

The meter 10 also comprises a phase conductor 16, which is connected to the phase line 14 of the distribution network 12 via the upstream phase terminal P and interconnects the upstream phase terminal P and the downstream phase terminal P′. The meter 10 also comprises a neutral conductor 17, which is connected to the neutral line 15 of the distribution network 12 via the upstream neutral N and terminal terminal N and the interconnects the upstream neutral downstream neutral terminal N′.

In this case, the meter 10 also comprises a cut-off member 18 comprising a switch assembled on the phase conductor 16. The cut-off member 18 is used in particular for remotely interrupting or re-establishing the supply of power to the installation 11, e.g. in the event of the subscription being cancelled or the subscription contract not being complied with.

The meter 10 also comprises metrological components.

These metrological components comprise a voltage sensor (not shown) which measures the voltage applied by the network 12 to the terminals of the installation 11 (and of the meter 10).

The metrological components also comprise a current measurement device 20, which is assembled on the phase conductor 16 upstream of the cut-off member 18. The current measurement device 20 makes it possible to measure the current I that flows on the phase line 14 and on the phase conductor 16 and that is supplied to the installation 11 by the distribution network 12.

Here, the meter 10 includes at least one temperature sensor (two in this case). These sensors comprise a temperature sensor 21, which is positioned close to the current measurement device 20. The temperature sensor 21 produces temperature measurements that are representative of the temperature of the current measurement device 20 and its immediate surroundings. The role of this temperature sensor 21 will be described later.

The meter 10 further comprises a processing unit 22 (electronic and software). The processing unit 22 comprises at least one processing component 23, which is, for example, a “general-purpose” processor, a processor specialising in signal processing (digital signal processor (DSP)), a microcontroller, a programmable logic circuit, such as an FPGA (field-programmable gate array) or an ASIC (application-specific integrated circuit). The processing unit 22 also comprises one or more memories 24 connected to or integrated in the processing component 23. At least one of these memories 24 forms a computer-readable storage medium on which at least one computer program is stored, said computer program comprising instructions which cause the processing unit 22 to execute the steps of the current measurement method, which will be described later.

In this case, the processing unit 22 comprises a “metrology” microcontroller 23a which in particular acquires the measurements taken by the sensors of the meter 10 and carries out certain processing operations on said measurements, and an “application” microcontroller 23b, which in particular controls the cut-off member 18. The current measurement method is implemented in the metrology microcontroller 23a.

The current measurement device 20 specifically will now be discussed.

The current measurement device 20 allows a main current passing through said device to be measured. The main current in this case is the current I flowing on the phase line 14 and the phase conductor 16 and consumed by the installation 11.

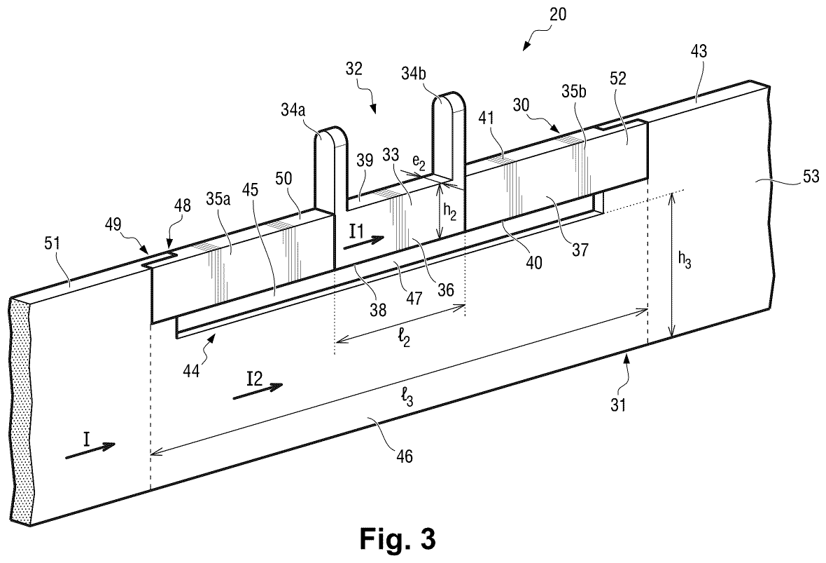

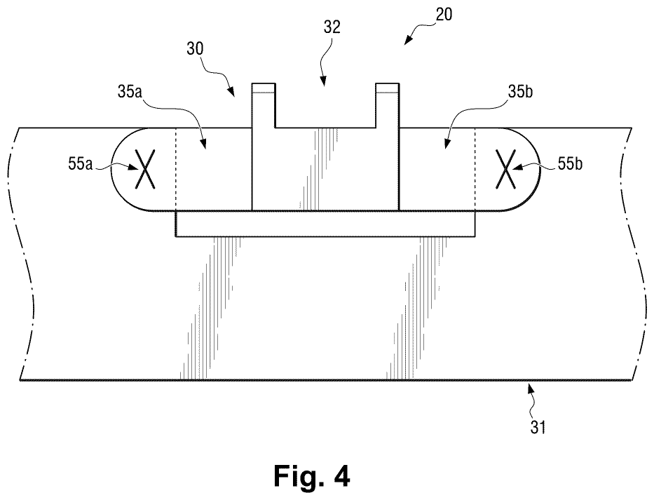

With reference to FIGS. 3 and 4, in one embodiment the current measurement device 20 comprises two parts fastened to each other: a first part 30 and a second part 31.

The first part 30 comprises a shunt 32.

The shunt 32 comprises a main segment 33 in the form of a rectangular plate, and a first terminal 34a and a second terminal 34b located at the ends of the main segment 33.

The two terminals 34a, 34b each extend from the same side of the main segment 33, perpendicularly to the length of the main segment 33.

The shunt 32 is made of at least one material, in this case comprising Manganin (CuMn12Ni).

The first part 30 furthermore comprises plates 35a, 35b, in this case made of copper, which are fastened to the ends of the shunt 32 on either side thereof. The plates 35a, 35b are, for example, welded to the ends of the shunt 32. The side faces 36 of the shunt 32 and the side faces 37 of the plates 35a, 35b are coplanar. The underside 38 and top surface 39 of the shunt 32 are coplanar, as are the underside 40 and top surface 41 of the plates 35a, 35b.

Here, the term “top surface” means on the side having the terminals 34a, 34b of the shunt 32, and the term “underside” means the other side.

The first part 30 thus forms a first element which is electrically conductive.

The second part 31 is generally in the shape of a rectangular plate.

The second part 31 is made of at least one material, in this case comprising a copper alloy, for example Cu-ETP C11000.

The second part 31 comprises a side 43 (its upper length in this case) in which there is formed a notch 44 that defines a recessed portion 45 extending along a segment of the length of the second part 31, and a non-recessed portion 46 extending along said segment of the length of the second part 31.

The non-recessed portion 46 forms a second element which is electrically conductive. The second element 46 is therefore a segment of the second part 31.

The first element 30 extends into the notch 44 so as to leave a non-electrically conductive space 47 between the first element 30 and the second element 46. This space 47 is empty in this case, but it could be filled with a non-conductive material.

Here, each end of the first element 30 comprises a first cavity 48 formed in its body, and each end of the second element 46 comprises a second cavity 49 formed in its body. The first element 30 and the second element 46 have their ends nested in such a way that the bottom of the first cavity 48 in each end of the first element 30 abuts the bottom of the second cavity 49 in a separate end of the second element 46.

Each end of the first element 30 is fastened to a separate end of the second element 46 by an electrically conductive connection. In this case, each electrically conductive connection is established by an electrical spot-welding operation. Spot-welding two metal bodies involves maintaining a high pressure between the two metal bodies that are to be welded. A very high electric current is then applied for a very short period of time by means of electrodes. This electric current heats the contact surfaces, which remain fastened together as they cool.

The position of the spot welds 55a, 55b can be seen in FIG. 4.

It should also be noted that the top surface 50 of the first element 30 and the top surface 51 of the second part 31 are coplanar, and that the side faces 52 of the first element 30 and the side faces 53 of the second part 31 are coplanar.

Thus, when the main current I passes through the current measurement device 20, the main current is split into a first current I1 flowing in the first element 30 and a second I2 flowing in the second element 46. The current current measurement device 20 therefore comprises a current splitter comprising a first branch formed by the first element 30 and a second branch formed by the second element 46. The main current I is distributed between the two branches according to their respective impedances.

Part of the current to be measured is therefore diverted from the main copper bar, which is formed by the second part 31, in particular by its non-recessed portion 46, into a secondary bar in which the measurement shunt 32 is located. The secondary bar is welded over the main copper bar.

The first current I1 is therefore representative of the main current I (it is a “resemblance” thereof).

Owing to the shunt 32, the impedance of the first element 30 is much greater than the impedance of the second element 46. The first current I1 passing through the first element 30 is thus much lower than that passing through the second element 46. The power dissipated in the shunt 32 is therefore much lower than when the entire main current passes through a shunt. Advantageously, the electrical resistance of the first element 30 is between 5 and 100 times the electrical resistance of the second element 46.

By way of example, the shunt 32 has a length l₂ of 10 mm, a height h₂ of 4 mm and a thickness e₂ of 1.79 mm, and therefore a cross section along a plane perpendicular to its length l₂ of 7.17 mm². The impedance of the shunt 32 at 20° C. is then 599.9 Q.

The two plates 35a, 35b each have a length of 10 mm, a height of 4 mm and a thickness of 1.79 mm. The total impedance of the two plates at 20° C. is 48.2μΩ.

The cross section of the first element 30 along a plane perpendicular to its length is 7.2 mm².

The total impedance of the first element 30 at 20° C. is 648.0μΩ.

The second element 46 has a length 13 of 30 mm, a height h₃ of 10 mm and a thickness of 1.79 mm. The cross section of the second element 46 along a plane perpendicular to its length is 17.9 mm².

The impedance of the second element 46 at 20° C. is 28.9μΩ.

It is therefore clear that the second element has a significantly lower resistance, which results from the difference in the resistance of the materials used (the resistance of Manganin is significantly higher than that of copper).

Thus, when a main current I of 200 A passes through the current measurement device 20, the first current I1 passing through the first element 30 is a current of 8.5 A, and the second current I2 passing through the second element 46 is a current of 191.5 A.

The main current I can therefore be evaluated on the basis of the measurement of the first current I1, and therefore on the basis of the measurement of the voltage across the terminals of the shunt 32.

The processing unit 22 measures the voltage across the terminals of the shunt 32 and then evaluates the main current I on the basis of said voltage. The processing unit 22 may optionally evaluate first the first current I1 on the basis of the voltage and then evaluate the main current I on the basis of the first current I1.

Ideally, the distribution of currents between the two branches should always remain the same regardless of the temperature, so that the measurement remains unchanged and the main current I can be obtained by multiplying the first current I1 (or the voltage across the terminals of the shunt 32) by a constant coefficient.

However, as has been seen, the shunt 32 comprises Manganin and the plate 31 comprises a copper alloy. These two materials do not have the same thermal resistance. The temperature drift of the resistance of copper is about 3.93×10⁻³/° C., while the resistance of Manganin drifts by 0.001×10⁻³/° C.

Depending on the temperature, therefore, the resistance of the second element 46 varies more quickly than that of the first element 30. The current in the shunt 32 thus varies depending on the temperature, thereby generating a measurement error.

Table 1 in the annex includes the voltage values across the terminals of the shunt 32 (in V) as a function of the temperature (between −40° C. and +70° C.), as well as the measurement error relating to the point measured at 20° C., which is the reference temperature during calibration of the meter 10.

It can be seen that the measurement error may be relatively large.

However, this measurement error can be compensated for by using temperature measurements produced by the aforementioned temperature sensor 21.

The processing unit 22 compensates, depending on said temperature measurements, for the temperature drift difference of the electrical resistance of the first element 30 and of the electrical resistance of the second element 46.

The processing unit 22:
measures a voltage across the terminals of the shunt 32;
acquires temperature measurements;
determines, depending on the temperature, a value of a compensation parameter for compensating for the temperature drift difference of the electrical resistance of the first element 30 and of the electrical resistance of the second element 46;
corrects the voltage across the terminals of the shunt 32 using said value of said compensation parameter;
evaluates the main current I on the basis of the corrected voltage.

In one embodiment, the compensation parameter is equal to a constant voltage value per unit of temperature. By way of example, this constant value is 17.9 mV/° C.

To the voltage measurement across the terminals of the shunt, the processing unit 22 adds the value of the compensation parameter corresponding to the measured temperature.

Table 2 in the annex is thus obtained.

It can be seen that the measurement error is significantly lower, reduced to lower values than the dimensions imposed by the standards.

It would of course be possible to compensate for the temperature drift difference in a different way or by using additional operations. It would be possible, for example, to additionally add a constant positive offset to the corrected voltage of Table 2 to further reduce the measurement error.

The invention thus makes it possible to measure high currents (for example 200 A or 320 A) using a standard shunt that is normally used for currents of less than 100 A.

In the region of the heating, the power dissipated at a current of 200 A in the current measurement device 20 is 1.11 W compared with 7.2 W in a “conventional” shunt. The power dissipated is therefore significantly reduced and is even less than the power of 1.46 W dissipated in a conventional shunt at 90 A.

The cost of the current measurement device is low because it uses a shunt of known (and inexpensive) design, as well as very inexpensive additional elements. The current measurement device can therefore be integrated into a pre-existing meter that was initially designed to measure low currents, without significantly modifying said meter, to obtain one capable of measuring high currents (typically greater than 100 A). The current sensor in particular is already present in the pre-existing meter in order to compensate for the temperature drift of the shunt.

It goes without saying that the invention is not limited to the described embodiment but covers any variant falling under the scope of the invention as defined by the claims.

The first element could comprise only the shunt, without the copper plates described herein positioned on either side of the shunt. The shunt could have a different shape.

Likewise, the second part and the second element could have a different shape.

It has been described that the first element is an “individual” part whereas the second element is a segment of a part (of the second part 31); indeed, the main current flows well in the second part on either side of the second element. This configuration is not mandatory, and the second element could also be an individual part welded to the first element. For example, the second element could comprise two arms, each fastened to one of the ends of the first element.

All the materials mentioned here could be different.

The electricity meter could be a multi-phase meter.

The apparatus in which the current measurement device is integrated need not necessarily be an electricity meter; it could be any apparatus within which current is measured.

### Annexes

TABLE 1

| | Shunt | |
|---|---|---|
| Temp. [° C.] | voltage [V] | Error [%] |
| −40 | 4.017 | −21.47% |
| −30 | 4.205 | −17.81% |
| −20 | 4.390 | −14.19% |
| 0 | 4.756 | −7.03% |
| 10 | 4.937 | −3.50% |
| 20 | 5.116 | 0.00% |
| 30 | 5.293 | 3.47% |
| 40 | 5.469 | 6.90% |
| 50 | 5.643 | 10.31% |
| 60 | 5.816 | 13.69% |
| 70 | 5.987 | 17.04% |

TABLE 2

| | Shunt | | Corrected | Corrected |
|---|---|---|---|---|
| Temp. [° C.] | voltage [V] | Error [%] | voltage [V] | error [%] |
| −40 | 4.017 | −21.47% | 5.091 | −0.48% |
| −30 | 4.205 | −17.81% | 5.100 | −0.32% |
| −20 | 4.390 | −14.19% | 5.106 | −0.19% |
| 0 | 4.756 | −7.03% | 5.114 | −0.03% |
| 10 | 4.937 | −3.50% | 5.116 | 0.00% |
| 20 | 5.116 | 0.00% | 5.116 | 0.00% |
| 30 | 5.293 | 3.47% | 5.114 | −0.03% |
| 40 | 5.469 | 6.90% | 5.111 | −0.09% |
| 50 | 5.643 | 10.31% | 5.106 | −0.19% |
| 60 | 5.816 | 13.69% | 5.100 | −0.31% |
| 70 | 5.987 | 17.04% | 5.092 | −0.46% |

1. A current measurement device arranged to measure a main current passing therethrough and comprising:
a first element which is electrically conductive and which includes a measurement shunt;
a second element which is electrically conductive, the second element being a segment of a part, said part being generally in the shape of a rectangular plate;
each end of the first element being fastened to a separate end of the second element by an electrically conductive connection such that the main current is split into a first current flowing in the first element and a second current flowing in the second element, the measurement shunt thus making it possible to measure the first current, which is representative of the main current.

2. The current measurement device according to claim 1, wherein said part comprises a side in which there is formed a notch that defines a recessed portion extending along a segment of a length of the part, and a non-recessed portion extending along said segment of the length of the part, the second element being said non-recessed portion, and the first element extending in the notch so as to leave a non-electrically conductive space between the first element and the second element.

3. The current measurement device according to claim 1, wherein each end of the first element comprises a first cavity formed in its body, and each end of the second element comprises a second cavity formed in its body, the first element and the second element having their ends nested in such a way that a bottom of the first cavity in each end of the first element abuts a bottom of the second cavity in a separate end of the second element.

4. The current measurement device according to claim 1, wherein the second element is made of at least one material comprising a copper alloy.

5. The current measurement device according to claim 1, wherein the first element comprises the measurement shunt and two plates, which are fastened to the measurement shunt and positioned on either side of the measurement shunt.

6. The current measurement device according to claim 1, wherein the measurement shunt is made of at least one material comprising Manganin.

7. The current measurement device according to claim 1, wherein each electrically conductive connection is established by a spot-welding operation.

8. The current measurement device according to claim 1, wherein an electrical resistance of the first element is between 5 times and 100 times an electrical resistance of the second element.

9. An electrical apparatus including the current measurement device according to claim 1, the electrical apparatus comprising a processing unit arranged to:
measure a voltage across the terminals of the measurement shunt;
evaluate the main current on the basis of said voltage.

10. The electrical apparatus according to claim 9, further comprising a temperature sensor, the processing unit being further arranged to acquire temperature measurements produced by the temperature sensor and to compensate, depending on said temperature measurements, for a temperature drift difference of an electrical resistance of the first element and an electrical resistance of the second element.

11. The electrical apparatus according to claim 9, the electrical apparatus being an electricity meter.

12. The electrical apparatus according to claim 9, the electrical apparatus being arranged to measure a main current greater than 100 A using the current measurement device.

13. A current measurement method, carried out in a processing unit of the electrical apparatus according to claim 10 and comprising the steps of:
measuring a voltage across the terminals of the measurement shunt;
acquiring the temperature measurements produced by the temperature sensor;
determining, depending on the temperature, a value of a compensation parameter for compensating for the temperature drift difference of the electrical resistance of the first element and of the electrical resistance of the second element;
correcting the voltage across the terminals of the measurement shunt using said value of said compensation parameter;
evaluating the main current on the basis of the corrected voltage.

14. (canceled)

15. A non-transitory computer-readable storage medium on which a computer program is stored, wherein the computer program comprises instructions that cause a processing unit of an electrical apparatus to execute the steps of the current measurement method according to claim 13.
